(19) United States
(12) Patent Application Publication
(10) Pub. No.: US 2012/0318669 A1
(43) Pub. Date: Dec. 20, 2012

(54) SPUTTERING TARGET-BACKING PLATE ASSEMBLY

(75) Inventors: Yuki Ikeda, Ibaraki (JP); Yuichiro Nakamura, Ibaraki (JP); Atsutoshi Arakawa, Ibaraki (JP)

(73) Assignee: JX NIPPON MINING & METALS CORPORATION, Tokyo (JP)

(21) Appl. No.: 13/579,606

(22) PCT Filed: Feb. 16, 2011
(86) PCT No.: PCT/JP2011/053211

§ 371 Date: Sep. 7, 2012

(30) Foreign Application Priority Data
Feb. 19, 2010 (JP) 2010-035282

(51) Int. Cl. C23C 14/06; B05D 5/12; B32B 15/04; C23C 14/08

(52) U.S. Cl. 204/298.13; 427/58; 427/126.1; 427/126.3

(57) ABSTRACT

Provided is a sputtering target-backing plate assembly where a raw material powder prepared so as to have the composition of a magnetic material sputtering target is filled in a die together with a backing plate and hot-pressed, thereby being bonded to the backing plate simultaneously with sintering of the magnetic material target powder.

It is an object of the present invention to provide a sputtering target-backing plate assembly having a high average pass through flux and allowing more stable sputtering, by disposing the raw material powder for a target on the backing plate and sintering them.

By simultaneously performing sintering and bonding, a sputtering target-backing plate assembly has a shorter manufacturing process, can shorten manufacturing period, and does not cause a problem of detachment due to an increase in temperature during sputtering. In addition, it is also an object of the present invention to provide a sputtering target-backing plate assembly at a reduced cost and with an improved average pass through flux (PTF).

### BACKGROUND OF THE INVENTION

The present invention relates to a sputtering target-backing plate assembly having an improved pass through flux (PTF).

Recently, sputtering, which can easily adjust the thickness and the component of a film in formation of the film, is widely used as a method of forming films of materials for electronic/electrical parts.

This sputtering method is based on the following principle: A positive electrode and a negative electrode serving as a target are arranged to oppose each other, and a high voltage is applied between the substrate and the target under an inert gas atmosphere to generate an electric field. In this case, ionized electrons collide with the inert gas and generate plasma. The cations in the plasma collide with the target (negative electrode) surface to make the target constituent atoms fly out from the target and to allow the flying out atoms to adhere to the opposing substrate surface to form a film.

In the case of using this sputtering method, the shape and the characteristics of a target highly affect the properties of a thin film formed on a substrate. And the use of inventiveness in the process of producing the target affects the production cost.

In general, the type of a sputtering system determines the available shape of a sputtering target. A target itself is generally used without being bonded to a backing plate. In such a case, the target itself also serves as a backing plate.

However, for reducing the price of a sputtering target, or an improvement in pass through flux, if needed, the target is bonded to a backing plate and an inexpensive non-magnetic material, which are commonly practiced.

In a general bonding method, a brazing material such as indium (In) is used. In this method, however, the temperature of the sputtering target increases during sputtering to a temperature higher than the melting point of the brazing material. This causes a problem of de-bonding.

As a method of solving the problems, so-called diffusion bonding is known. The method does not use any brazing material, and a sputtering target material and a backing plate are kept in contact with each other and are then exposed to high temperature and pressure to perform solid-phase diffusion. Here, the sputtering target and the backing plate need to be respectively subjected to machining in advance, resulting in defects of an increase in number of steps and in cost.

In the case of producing hard disks, magnetron sputtering of a magnetic material is generally performed. However, the sputtering target of the magnetic material contains a noble metal and is expensive in many cases. Furthermore, a high magnetic permeability makes the pass through flux insufficient, resulting in problems such as unstable discharge or no discharge.

Thus, in use of magnetic materials and for improvement of the pass through flux (PTF), a target having a higher PTF is required and the following attempts have been made: replacing a material at a portion that is not eroded, i.e., a portion corresponding to the backing plate, for a material having PTF as high as possible, and separately producing a target and a backing plate (by sintering, for example) and bonding them with a brazing material or by solid-phase diffusion.

As described above, however, in these bonding methods, both the target and the backing plate need to be cut into appropriate shapes in advance so as not to generate gaps when they are brought into contact each other. This must be conducted even with a specific material, e.g., a magnetic material that causes detachment during sputtering at the interface between the target and the backing plate. Thus, there is a similar problem as in the general target-backing plate assembly described above.

Furthermore, in the conventional technologies, bonding of a target to a backing plate is one method for cost reduction. However, the backing plate usually has a planar shape, and the thickness to be eroded can be thin. Hence, the method is effective for sputtering a small amount as conducted in research institutes, but is unsuitable for sputtering amount for mass production of hard disks.

The same occurs in the case of using a brazing material, the case of diffusion bonding, and the case of simultaneously sintering a powder and a backing plate. Accordingly, only a mere reduction in thickness of the backing plate cannot achieve the intended purpose, i.e., cost reduction.

In these circumstances, both cost reduction and a high pass through flux can be achieved in a particular bonding method as by changing thickness of the backing plate according to the erosion shapes which have a portion to be deeply eroded and a portion to be shallowly eroded. In this method, a powder and a backing plate are simultaneously sintered.

In the method using a brazing material or diffusion bonding, there are defects: the target base material to be prepared cannot be reduced in size, and a machining step is necessary prior to bonding, which prevents cost reduction.

As described above, in bonding molded solids each other with a bonding material, a problem is with bonding strength in the bonding portion, whereas in diffusion bonding of molded solids has a problem of production cost due to complexity of the production process.

With conventionally known technologies, as a means for reducing the number of steps for sintering a W-Ti target powder and a backing plate, a method is proposed; where a powder prepared so as to have a composition of a sputtering target material is filled in a capsule together with a backing plate and is subjected to HIP treatment (Refer to Patent Literature 1). In this case, the sintering step of the sputtering target and the bonding step to the backing plate are performed at the same time, but the steps are complicated and must employ expensive HIP treatment due to peculiarity of the target material.

Furthermore, a method of preventing de-bonding during sputtering in bonding of a target insert to a supporting plate is disclosed (Refer to Patent Literature 2), where the target insert is produced in advance by molding a high purity powder such as a tungsten powder and directly compressing to the supporting plate having a concave to cause solid-phase diffusion.

Furthermore, a method where a base metal ingot is placed on a pressurized powder composed of a base metal and a dispersed metal, the ingot is melted to allow the metal to permeate into the pores of the pressurized powder and to thereby to bond thereto, and a part of the ingot is used as a backing plate is disclosed (Refer to Patent Literature 3).

In addition, a method where a ceramic target plate having a metal adhering to the periphery thereof is placed on an ashtray-shape backing plate made of Cu and is hot-pressed and thereby bonded to the backing plate is disclosed (Refer to Patent Literature 4). The purposes of this method are cooling and prevention of cracking. Furthermore, a method where a target containing an aluminum component, a target material powder, and a backing plate material powder are cold-pressed and then subjected to hot forging press is disclosed (Refer to Patent Literature 5).

In these known technologies, however, concrete means for solving the magnetic material target-specific problems are not disclosed.
[Patent Literature 1] U.S. Pat. No. 5,397,050
[Patent Literature 2] Japanese Unexamined Patent Application Publication No. 2004-530048
[Patent Literature 3] Japanese Unexamined Patent Application Publication No. 2004-002938
[Patent Literature 4] Japanese Unexamined Patent Application Publication No. H07-18432
[Patent Literature 5] Japanese Patent No. 4226900

### SUMMARY OF THE INVENTION

### Problem to be Solved by the Invention

It is an object of the present invention to provide a sputtering target-backing plate assembly having a high average pass through flux and capable of stable sputtering, by disposing a target raw material powder on a backing plate and sintering them. The number of production steps is decreased by performing sintering and bonding at the same time to shorten manufacturing period, and the assembly does not cause a problem of detachment due to an increase in temperature during sputtering.

It is also an object of the present invention to provide a sputtering target-backing plate assembly at a reduced cost and with an improved pass through flux (PTF) by enabling use of a backing plate having a thin portion to be deeply eroded and a thick portion to be shallowly eroded and thereby further reducing the thickness of an expensive target.

### Means for Solving the Problem

The present invention provides:

1) a sputtering target-backing plate assembly where a raw material powder prepared so as to have the composition of a magnetic material sputtering target is filled in a die together with a backing plate and is hot-pressed, thereby being bonded to the backing plate simultaneously with sintering of the magnetic material target powder.;

2) the sputtering target-backing plate assembly according to 1) above, wherein the magnetic material target is of a material where at least one inorganic material selected from carbon, oxides, nitrides, carbides, and carbonitrides is finely dispersed in a metal phase;

3) the sputtering target-backing plate assembly according to 1) or 2) above above, wherein the magnetic material target comprises 18 mol % or less of Cr and/or 25 mol % or less of Pt, and the remainder of Co and inevitable impurities;

4) the sputtering target-backing plate assembly according to 1) or 2) above, wherein the magnetic material target comprises 18 mol % or less of Cr and/or 45 mol % or less of Pt, and the remainder of Fe and inevitable impurities;

5) the sputtering target-backing plate assembly according to of 3) or 4) above, wherein the magnetic material target further comprises at least one element selected from Ru, Ti, Ta, Si, B, and C in a total amount of 12 mol % or less; and

6) the sputtering target-backing plate assembly according to any one of 3) to 5) above, wherein the magnetic material target further comprises an oxide, nitride, carbide, or carbonitride of at least one element selected from Si, Ti, Ta, Co, Cr, and B or carbon in a total amount of 5 to 15 mol %.

The present invention also provides:

7) the sputtering target-backing plate assembly according to any one of 1) to 6) above, wherein the backing plate has a lower magnetic permeability than that of the target;

8) the sputtering target-backing plate assembly according to any one of 1) to 7) above, wherein the backing plate is of a non-magnetic material having a magnetic permeability of 1.0 or less;

9) the sputtering target-backing plate assembly according to any one of 1) to 8) above, wherein the backing plate is of a metal phase only or a non-magnetic substance where at least one inorganic material selected from carbon, oxides, nitrides, carbides, and carbonitrides is finely dispersed in the metal phase;

10) the sputtering target-backing plate assembly according to 9) above, wherein the metal phase of the backing plate comprises Co and at least one element selected from Cr, Ti, Ta, Si, B, and C;

11) the sputtering target-backing plate assembly according to 9) or 10) above, wherein the inorganic material dispersed in the metal phase of the backing plate is an oxide, nitride, carbide, or carbonitride of at least one element selected from Si, Ti, Ta, Co, Cr, and B or carbon; and

12) the sputtering target-backing plate assembly according to any one of 1) to 11) above wherein the backing plate comprises 19 to 40 mol % of Cr, and an oxide, nitride, carbide, or carbonitride of at least one element selected from Si, Ti, Ta, Co, Cr, and B or carbon in a total amount of 5 to 15 mol %, and the remainder of Co and inevitable impurities.

The present invention further provides:

13) the sputtering target-backing plate assembly according to any one of 1) to 12) above, wherein a maximum difference between linear expansion coefficients of the backing plate and the magnetic material target is 0.5 or less in a range of room temperature to 1000° C.;

14) the sputtering target-backing plate assembly according to any one of 1) to 13) above, wherein the backing plate is produced using scrap or waste of the sputtering target as a raw material; and

15) a method of producing a sputtering target-backing plate assembly according to any one of 1) to 14) above, the method comprising filling a die with a raw material powder prepared so as to have the composition of a magnetic material sputtering target, together with a backing plate; and performing hot-pressing to sinter the magnetic material target powder and bonding the target to the backing plate at the same time.

### Effects of Invention

The present invention can provide a sputtering target-backing plate assembly having a high average pass through flux by producing the assembly by disposing a target raw material powder on a backing plate and sintering them. The present invention therefore has an excellent effect of allowing more stable sputtering to provide a product with a high quality.

In addition, since sintering and bonding are simultaneously performed, the number of production steps is decreased to shorten manufacturing period, and an effect of preventing a problem of detachment due to an increase in temperature during sputtering is obtained, unlike bonding using a brazing material such as In.

Furthermore, the present invention allows use of a backing plate having a thin portion to be deeply eroded and a thick portion to be shallowly eroded, thereby allows a reduction in thickness of an expensive target, and can provide a sputtering target-backing plate assembly at a reduced cost and with an improved pass through flux (PTF). In addition, the present invention has an effect of reducing the raw material cost compared with that of an integrated target by using a material not containing Pt for the portion not to be eroded.

As described above, the present invention has a significant effect of providing a technology that can provide a magnetic material sputtering target-backing plate assembly inexpensively and stably by simultaneously sintering a raw material powder prepared in a desired composition for a sputtering target and bonding the target to a backing plate.

### BRIEF DESCRIPTION OF THE DRAWINGS

FIG. 1 is an explanatory diagram schematically illustrating a bonded laminate composed of target and backing plate materials shown in Example 1.

FIG. 2 is an explanatory diagram schematically illustrating a tub-shape target-backing plate assembly shown in Examples 2 and 4. Here, a ‘tub-shape’ or a ‘tub-type’ is used to refer to an ‘ashtray shape’, and hereinafter.

FIG. 3 is a schematic diagram of an erosion profile when using a tub-shape backing plate of the present invention.

### DETAILED DESCRIPTION OF THE INVENTION

In the sputtering target-backing plate assembly of the present invention, a raw material powder prepared so as to have the composition of a magnetic material sputtering target is filled in a die together with a backing plate and is hot-pressed, thereby being bonded to the backing plate simultaneously with sintering of the magnetic material target powder. The backing plate may be used as a sintered compact or in a molten state.

The sputtering target-backing plate assembly can be easily produced by disposing the backing plate in a carbon graphite die, placing a raw material powder for a target on this backing plate, and performing hot-pressing in vacuum at a temperature of 1000 to 1200° C. and a pressure of 20 to 40 MPa for a holding time of 60 to 120 min.

Since sintering and bonding are thus performed at the same time, the number of production steps is decreased to shorten manufacturing period, and an effect of preventing a problem of detachment due to an increase in temperature during sputtering can be obtained, unlike bonding using a brazing material such as In.

Furthermore, the present invention allows use of a backing plate having a thin portion to be deeply eroded and a thick portion to be shallowly eroded, thereby allows a reduction in thickness of an expensive target, and achieves a reduction in cost and an improvement in pass through flux (PTF).

The sputtering target-backing plate assembly of the present invention can have a high average pass through flux and therefore has an excellent effect of allowing more stable sputtering to provide a product with a high quality.

In general, a PTF of 50% or more is required for performing stable sputtering in some apparatuses. The present invention has a considerable merit that, for example, even if the PTF of a target material is less than 50%, the PTF can be increased to 50% or more without increasing the thickness of the target. The present invention encompasses such a target.

The magnetic material target of the sputtering target-backing plate assembly of the present invention may be a material where at least one inorganic material selected from carbon, oxides, nitrides, carbides, and carbonitrides is finely dispersed in a metal phase. The magnetic material target of the sputtering target-backing plate assembly of the present invention can contain 18 mol % or less of Cr and/or 25 mol % or less of Pt, and the remainder of Co and inevitable impurities.

Alternatively, the magnetic material target of the sputtering target-backing plate assembly of the present invention can contain 18 mol % or less of Cr and/or 45 mol % or less of Pt, and the remainder of Fe and inevitable impurities.

The magnetic material target of the sputtering target-backing plate assembly of the present invention can further contain at least one element selected from Ru, Ti, Ta, Si, B, and C in a total amount of 12 mol % or less.

The magnetic material target of the sputtering target-backing plate assembly of the present invention can further contain an oxide, nitride, carbide, or carbonitride of at least one element selected from Si, Ti, Ta, Co, Cr, and B or carbon in a total amount of 5 to 15 mol %, in addition to the materials for the targets mentioned above. These targets are useful components as magnetic materials. The magnetic material target of the sputtering target-backing plate assembly of the present invention can have a high average pass through flux (e.g., 50% or more).

In the sputtering target-backing plate assembly of the present invention, the backing plate has a lower magnetic permeability than that of the target to increase the average pass through flux of the target and thereby to enable efficient sputtering. The backing plate is more preferably of a non-magnetic material having a magnetic permeability of 1.0 or less (CGS system of units, the same shall apply hereinafter). Thus, even if the target itself is made of a material having a high magnetic permeability of, for example, higher than 10, since the magnetic permeability of the backing plate is low, plasma is generated to enable sputtering. If the magnetic permeability of the backing plate is sufficiently low, the backing plate may be of a metal phase only or a non-magnetic substance where at least one inorganic material selected from carbon, oxides, nitrides, carbides, and carbonitrides is finely dispersed in a metal phase.

In order to implement this, the metal phase of the backing plate can contain Co and at least one element selected from Cr, Ti, Ta, Si, B, and C. Alternatively, the metal phase may contain Fe. Since both Co and Fe are ferromagnetic, it is necessary to adjust an additive for reducing the magnetic permeability of the backing plate or regulate the backing plate composition. In the sputtering target-backing plate assembly, the inorganic material dispersed in the metal phase of the backing plate can be an oxide, nitride, carbide, or carbonitride of at least one element selected from Si, Ti, Ta, Co, Cr, and B or carbon.

The present invention can provide a sputtering target-backing plate assembly having a backing plate containing 19 to 40 mol % of Cr, and an oxide, nitride, carbide, or carbonitride of at least one element selected from Si, Ti, Ta, Co, Cr, and B or carbon in a total amount of 5 to 15 mol %, and the remainder of Co and inevitable impurities.

In generally, the density of a sintered compact target is increased by using a fine powder as the raw material powder for the target; however, merely using a fine powder is not a purpose of the present invention. Here, a powder having an average particle diameter in a known range can be used. The powders in Examples and Comparative Examples described below are typical examples, and it should be easily understood that the present invention is not limited thereto.

The same applies to production of the backing plate. As described below, since the raw material powder for the backing plate material is mostly the same as that of the target, surplus material or scrap of the target can be used. That is, the sputtering target-backing plate assembly can be produced by using scrap or waste of the sputtering target as a raw material for the backing plate and optionally using a material that can adjust the pass through flux. However, it should be also easily understood that the material is not limited to surplus materials. Selection of the material is intended to increase the pass through flux. Any material may be used that does not cause a warp, for example, but that has strength suitable for holding a target from materials so as long as it can achieve the purpose. This can be easily obtained by sintering according to the present invention.

In the present invention, it is effective if the backing plate has a shape of an ashtray, in another word, a bathtub. The shape and the size of the bathtub-shape backing plate are adjusted depending on the shape of a target, but are not particularly limited otherwise.

In addition, the target-backing plate assembly itself also needs to be designed based on the type of a sputtering system, thus the design is not particularly limited otherwise.

FIG. 3 is a schematic diagram of an erosion profile of a target when using a tub-shape backing plate. In FIG. 3, the dotted line shows the backing plate, the alternate long and short dash line shows the target, and the solid line shows the erosion profile. In FIG. 3, the numerical values representing sizes are merely examples, and it should be easily understood that the present invention is not limited these numerical values.

In the target-backing plate assembly of the present invention, target erosion progresses in such a form. This erosion profile is merely intended to facilitate comprehension of the present invention, and the present invention can be more easily understood by referring to this erosion profile.

The hot-pressing conditions for producing the backing plate are not limited as long as the backing plate has an appropriate strength. The same applies to production of the bonded laminate of a target and a backing plate. In general, a carbon graphite die is used. A prepared backing plate is disposed in this die, a powder mixture for a magnetic material target is placed on the backing plate, and hot press bonding is performed in vacuum.

The temperature, pressure, and holding time of the hot press bonding are appropriately selected as long as a target-backing plate assembly has an appropriate strength, and the hot press bonding may be performed by any known method. It should be easily understood that the hot-pressing conditions are not the invention of this application, that the hot-pressing conditions in Examples and Comparative Examples below are typical examples usually performed, and that the present invention is not limited thereto.

The present invention can further provide a sputtering target-backing plate assembly showing a maximum difference between linear expansion coefficients of the backing plate and the magnetic material target is 0.5 or less in a range of room temperature to 1000° C. The target can be prevented from warping by reducing this difference in linear expansion coefficient. As described above, the sputtering target-backing plate assembly can have a high average pass through flux (e.g., 50% or more) and therefore, has an excellent effect of allowing more stable sputtering to provide a product with a high quality can be provided.

### EXAMPLES

Examples are now explained. Note that these examples are merely illustrative and do not limit the present invention. Namely, other examples and modifications within the technical idea of the present invention are included in the present invention.

### Example 1

For a powder mixture for magnetic material target, prepared were a Co powder having an average particle diameter of 1 μm, a Cr powder having an average particle diameter of 2 μm, a Pt powder having an average particle diameter of 2 μm, a SiO₂ powder having an average particle diameter of 1 μm, and a CoO powder having an average particle diameter of 3 μm. The raw material powders were mixed at a composition of Co-17Cr-15Pt-5SiO₂-8CoO (mol %) with a mixer.

Separately, for a backing plate, similarly prepared were a Co powder having an average particle diameter of 1 μm, a Cr powder having an average particle diameter of 2 μm, and a SiO₂ powder having an average particle diameter of 1 μm (the particle diameters of these powders have no importance and are therefore not shown, and surplus powders for the target can be used. The same shall apply hereinafter). These powders were mixed at a composition of Co-25Cr-9SiO₂ (mol %), hot-pressed and subjected to machining to prepare a backing plate.

The magnetic permeability of this backing plate measured with a B-H meter (analyzer) was 1.0. The magnetic permeability of the target was significantly higher than this value.

In production of a backing plate, strict control in particle size of powders is not necessary, and surplus materials of a target may be used. The production process is not limited to hot-pressing, and any process that can provide appropriate strength can be employed. This applies hereinafter.

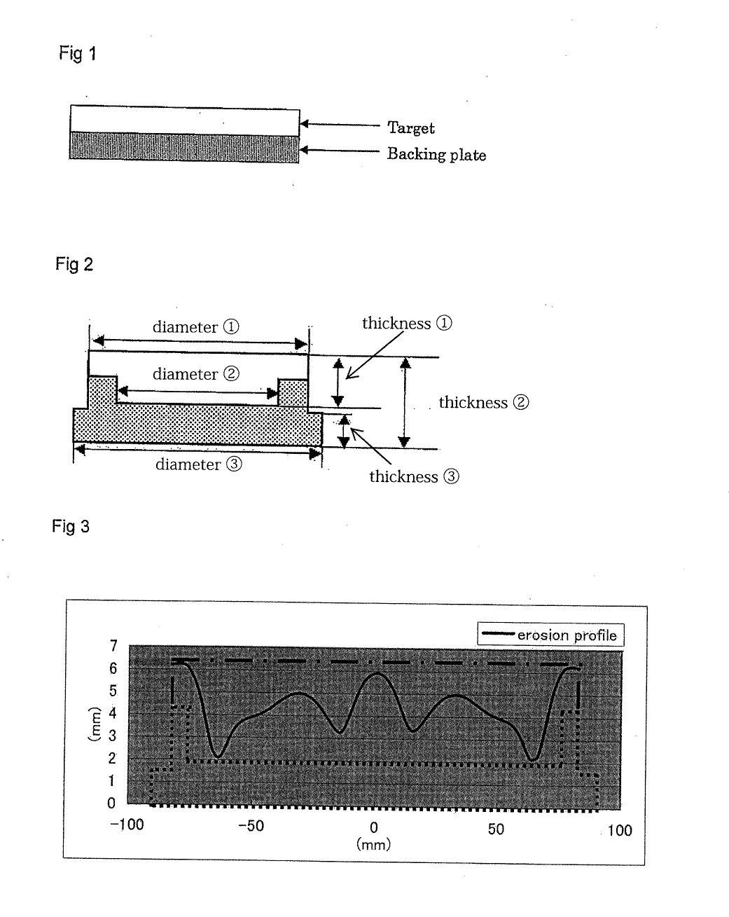

And the backing plate produced above was disposed in a carbon graphite die, and the powder mixture for a magnetic material target was filled on this backing plate. Then, hot-pressing was performed in vacuum at a temperature of 1100° C. and a pressure of 30 MPa for a holding time of 90 min. Thus, sintering and bonding were simultaneously performed to obtain a bonded laminate composed of a target and a backing plate shown in FIG. 1.

The linear expansion coefficients of the target and the backing plate were measured with a thermomechanical analysis apparatus (TMA-8310E1, manufactured by Rigaku Corp.). The linear expansion coefficients of the target were 1.4% at 1000° C., 0.9% at 500° C., and 0.4% at 100° C., whereas the linear expansion coefficients of the backing plate were 1.2% at 1000° C., 0.7% at 500° C., and 0.3% at 100° C. Therefore, the maximum difference in linear expansion coefficient was 0.2 in a range of room temperature to 1000° C. Thus, the linear expansion coefficients of the target and the backing plate were notably proximate each other, and thereby there was absolutely no concern about warping, detachment, and cracking with the target.

The bonded laminate composed of the target and the backing plate was machined so that the diameter was 165.10 mm, the thickness of the backing plate portion was 2.00 mm, and the thickness of the target portion was 4.35 mm to obtain a sputtering target-backing plate assembly. This assembly had an average pass through flux (PTF) of 53.0%. Since the assembly had such a high pass through flux (PTF), sputtering was easily performed. Table 1 summarizes the results.

The pass through flux measurement was performed in accordance with ASTM F2086-01 (Standard Test Method for Pass Through Flux of Circular Magnetic Sputtering Targets, Method 2). The center of the target was fixed, and the target was turned by 0 degree, 30 degrees, 60 degrees, 90 degrees, 120 degrees, 150 degrees, 180 degrees, 210 degrees, 240 degrees, 270 degrees, 300 degrees, and 330 degrees. The pass through flux was measured at each angle, and the measured value was divided by the value of a reference field defined in ASTM. Each result was converted to a percentage by multiplying 100, and the average value of the results at the 12 points above is shown as average pass through flux (%) in Table 1.

TABLE 1

| | | | | Maximum difference in | | Average |
|---|---|---|---|---|---|---|
| | | | Material properties of | linear expansion | | pass |
| | | | backing plate | coefficient | | through |
| | | Material properties of target | (portion not to be | from room temperature | Pressing | flux |
| | | (portion to be eroded) | eroded) | to 1000° C. | conditions | (%) |
| Example 1 | composite | Co—17Cr—15Pt—5SiO₂—8CoO | Co—25Cr—9SiO₂ | 0.2 | 1100° C., 30 MPa, | 53.0 |
| | | | | | 90 min | |
| Example 2 | composite | Co—17Cr—15Pt—5SiO₂—8CoO | Co—25Cr—9SiO₂ | 0.2 | 1100° C., 30 Mpa, | 54.0 |
| | (tub-type) | | | | 90 min | |
| Example 3 | composite | Co—15Cr—18Pt—5Ru—4TiO₂—8CoO | Co—25Cr—10SiO₂ | 0.3 | 1100° C., 30 MPa, | 51.0 |
| | | | | | 90 min | |
| Example 4 | composite | Co—15Cr—18Pt—5Ru—4TiO₂—8CoO | Co—25Cr—10SiO₂ | 0.3 | 1100° C., 30 MPa, | 52.2 |
| | (tub-type) | | | | 90 min | |
| Comparative | integrated | Co—17Cr—15Pt—5SiO₂—8CoO | — | — | 1100° C., 30 MPa, | 45.0 |
| Example 1 | type | | | | 90 min | |
| Comparative | integrated | Co—15Cr—18Pt—5Ru—4TiO₂—8CoO | — | — | 1100° C., 30 MPa, | 43.4 |
| Example 2 | type | | | | 90 min | |
| Example 5 | composite | Co—16Cr—10Pt—3TiO₂—3SiO₂ | Co—25Cr—3TiO₂ | 0.2 | 1100° C., 30 MPa, | 50.0 |
| | | | | | 90 min | |
| Example 6 | composite | Co—16Cr—10Pt—3TiO₂—3SiO₂ | Co—25Cr—3TiO₂ | 0.2 | 1100° C., 30 MPa, | 50.5 |
| | (tub-type) | | | | 90 min | |
| Example 7 | composite | Co—16Cr—3TiO₂—2SiO₂—3Cr₂O₃ | Co—22Cr—2Ta₂O₅ | 0.5 | 1100° C., 30 MPa, | 50.8 |
| | | | | | 90 min | |
| Example 8 | composite | Co—16Cr—3TiO₂—2SiO₂—3Cr₂O₃ | Co—22Cr—2Ta₂O₅ | 0.5 | 1100° C., 30 MPa, | 51.4 |
| | (tub-type) | | | | 90 min | |
| Example 9 | composite | Fe—41Pt—9SiO₂ | Co—25Cr—9SiO₂ | 0.3 | 1100° C., 30 MPa, | 92.5 |
| | | | | | 90 min | |
| Example 10 | composite | Fe—41Pt—9SiO₂ | Co—25Cr—9SiO₂ | 0.3 | 1100° C., 30 MPa, | 94.0 |
| | (tub-type) | | | | 90 min | |

### Comparative Example 1

As in Example 1, for a powder for magnetic material target, prepared were a Co powder having an average particle diameter of 1 μm, a Cr powder having an average particle diameter of 2 μm, a Pt powder having an average particle diameter of 2 μm, a SiO₂ powder having an average particle diameter of 1 μm, and a CoO powder having an average particle diameter of 3 μm, and these powders were mixed at a target composition of Co-17Cr-15Pt-5SiO₂-8CoO (mol %) with a mixer.

The powder was placed in a carbon graphite die and was hot-pressed in vacuum at a temperature of 1100° C. and a pressure of 30 MPa for a holding time of 90 min. In this case, no backing plate was used. The thus produced target material was machined to a diameter of 165.1 mm and a thickness of 6.35 mm. The average pass through flux (PTF) of this target was 45.0%.

An average pass through flux of 45.0% did not cause electric discharge, though it may differ depending on the sputtering system, and was in a state that did not allow sputtering. Table 1 also shows this result.

### Example 2

As in Example 1, for a powder for a magnetic material target, prepared were a Co powder having an average particle diameter of 1 μm, a Cr powder having an average particle diameter of 2 μm, a Pt powder having an average particle diameter of 2 μm, a SiO₂ powder having an average particle diameter of 1 μm, and a CoO powder having an average particle diameter of 3 μm, and these powders were mixed at a target composition of Co-17Cr-15Pt-5SiO₂-8CoO (mol %) with a mixer.

Separately, for a backing plate, similarly prepared were a Co powder, a Cr powder, and a SiO₂ powder. These powders were mixed at a composition of Co-25Cr-9SiO₂ (mol %), hot-pressed and subjected to machining to prepare a backing plate.

The magnetic permeability of this backing plate measured with a B-H meter (analyzer) was 1.0. The magnetic permeability of the target was significantly higher than this value.

The backing plate was machined to have an ashtray-like shape (in another word, tub-shape) having an inner diameter of 153.79 mm. The backing plate material was disposed in a carbon graphite die, and the raw material powder for a target was placed on the backing plate material. Then, hot-pressing was performed in vacuum at a temperature of 1100° C. and a pressure of 30 MPa for a holding time of 90 min to obtain a bonded laminate composed of target and backing plate materials.

This bonded laminate was further machined to obtain a target-backing plate assembly, which is shown in FIG. 2. The shape and the size of the assembly in FIG. 2 are as follows: diameter (1): 162.02 mm, diameter (2): 153.79 mm, diameter (3): 165.15 mm, thickness (1): 4.37 mm, thickness (2): 6.45 mm, and thickness (3): 1.75 mm. The thicknesses of the thickest portion and the thinnest portion of the backing plate were adjusted to be 4.45 mm and 2.08 mm, respectively. Since the backing plate thus was tub-shape, there was absolutely no concern about warping, detachment, and cracking with the target.

The average pass through flux (PTF) of this assembly was 54.0% and was further improved compared with that in Example 1. Since the pass through flux (PTF) was thus high, sputtering was easily performed. Table 1 also shows this result.

### Example 3

For a raw material powder for a magnetic material target, prepared were a Co powder having an average particle diameter of 1 μm, a Cr powder having an average particle diameter of 2 μm, a Pt powder having an average particle diameter of 2 μm, a Ru powder having an average particle diameter of 3 μm, a TiO₂ powder having an average particle diameter of 1 μm, and a CoO powder having an average particle diameter of 3 μm, and these powders were mixed at a composition of Co-15Cr-18Pt-5Ru-4TiO₂-8CoO (mol %) with a mixer.

Separately, for a backing plate, similarly prepared were a Co powder, a Cr powder, and a SiO₂ powder. These powders were mixed at a composition of Co-25Cr-10SiO₂ (mol %), hot-pressed and subjected to machining to prepare a backing plate material.

The magnetic permeability of this backing plate measured with a B-H meter (analyzer) was 1.0. The magnetic permeability of the target was significantly higher than this value.

And the backing plate material was disposed in a carbon graphite die, and the raw material powder for a target was placed on this backing plate material. Then, hot-pressing was performed in vacuum at a temperature of 1100° C. and a pressure of 30 MPa for a holding time of 90 min to obtain a bonded laminate composed of target and backing plate materials shown in FIG. 1.

The linear expansion coefficients of the target were 0.7% at 1000° C., 0.3% at 500° C., and 0.2% at 100° C., whereas the linear expansion coefficients of the backing plate were 1.0% at 1000° C., 0.5% at 500° C., and 0.2% at 100° C. Therefore, the maximum difference in linear expansion coefficient was 0.3 in a range of room temperature to 1000° C. Thus, the linear expansion coefficients of the target and the backing plate were notably proximate each other, and thereby there was absolutely no concern about warping, detachment, and cracking with the target.

The bonded laminate composed of the target and the backing plate was machined so that the diameter was 165.08 mm, the thickness of the backing plate portion was 2.05 mm, and the thickness of the target portion was 4.38 mm to obtain a sputtering target-backing plate assembly (the composition of the backing plate was Co-25Cr-10SiO₂ (mol %)). The assembly had an average pass through flux (PTF) of 51.0%. Since the assembly had such a high pass through flux (PTF), sputtering was possible. Table 1 shows this result.

### Example 4

As in Example 3, for a raw material powder for a magnetic material target, prepared were a Co powder having an average particle diameter of 1 μm, a Cr powder having an average particle diameter of 2 μm, a Pt powder having an average particle diameter of 2 μm, a Ru powder having an average particle diameter of 3 μm, a TiO₂ powder having an average particle diameter of 1 μm, and a CoO powder having an average particle diameter of 3 μm, and these powders were mixed at a composition of Co-15Cr-18Pt-5Ru-4TiO₂-8CoO (mol %) with a mixer.

Separately, for a backing plate, similarly prepared were a Co powder, a Cr powder, and a SiO2 powder. These powders were mixed at a composition of Co-25Cr-10SiO₂ (mol %), hot-pressed and subjected to machining to prepare a backing plate material.

The magnetic permeability of this backing plate measured with a B-H meter (analyzer) was 1.0. The magnetic permeability of the target was significantly higher than this value.

The backing plate was machined to have a tub-shape having an inner diameter of 153.75 mm as in Example 2. The prepared backing plate was disposed in a carbon graphite die, and the target powder was placed on this backing plate material. Then, hot-pressing was performed in vacuum at a temperature of 1100° C. and a pressure of 30 MPa for a holding time of 90 min to obtain a bonded laminate composed of target and backing plate materials.

This bonded laminate was further machined to obtain a target-backing plate assembly, which is shown in FIG. 2. The shape and the size of the assembly in FIG. 2 are as follows: diameter (1): 161.98 mm, diameter (2): 153.75 mm, diameter (3): 165.18 mm, thickness (1): 4.35 mm, thickness (2): 6.38 mm, and thickness (3): 1.76 mm. The thicknesses of the thickest portion and the thinnest portion of the backing plate were adjusted to be 4.42 mm and 2.03 mm, respectively. Since the backing plate thus was tub-shape, there was absolutely no concern about warping, detachment, and cracking with the target.

The average pass through flux (PTF) of this assembly was 52.2% and was further improved compared with that in Example 3. Since the pass through flux (PTF) was thus high, sputtering was easily performed. Table 1 also shows this result.

### Comparative Example 2

As in Example 3, for a raw material powder for a magnetic material target, prepared were a Co powder having an average particle diameter of 1 μm, a Cr powder having an average particle diameter of 2 μm, a Pt powder having an average particle diameter of 2 μm, a Ru powder having an average particle diameter of 3 μm, a TiO₂ powder having an average particle diameter of 1 μm, and a CoO powder having an average particle diameter of 3 μm. The powders were mixed at a composition of Co-15Cr-18Pt-5Ru-4TiO₂-8CoO (mol %) with a mixer.

The powder mixture was placed in a carbon graphite die and was hot-pressed in vacuum at a temperature of 1100° C. and a pressure of 30 MPa for a holding time of 90 min. In this case, no backing plate was used. The thus produced target material was machined to a diameter of 165.1 mm and a thickness of 6.35 mm. The average pass through flux (PTF) of this target was 43.4%.

An average pass through flux of 43.4% did not cause electric discharge, though it may differ depending on the sputtering system, and was in a state that did not allow sputtering. Table 1 also shows this result.

It can be understood from Comparative Examples 1 and 2 that a magnetic material target prepared by a simple production process (a process of producing an integrated type) has a low pass through flux (PTF) and thereby cannot be used for sputtering.

### Example 5

For a raw material powder for a magnetic material target, prepared were a Co powder having an average particle diameter of 1 μm, a Cr powder having an average particle diameter of 2 μm, a Pt powder having an average particle diameter of 2 μm, a TiO₂ powder having an average particle diameter of 1 μm, and a SiO₂ powder having an average particle diameter of 1 μm, and these were mixed at a composition of Co-16Cr-10Pt-3TiO₂-3SiO₂ (mol %) with a mixer.

Separately, for a backing plate, similarly prepared were a Co powder, a Cr powder, and a TiO₂ powder. These powders were mixed at a composition of Co-25Cr-3TiO₂ (mol %), hot-pressed and subjected to machining to prepare a backing plate material.

The magnetic permeability of this backing plate measured with a B-H meter (analyzer) was 1.0. The magnetic permeability of the target was significantly higher than this value.

And, the backing plate material was disposed in a carbon graphite die, and the raw material powder for a target was placed on this backing plate material. Then, hot-pressing was performed in vacuum at a temperature of 1100° C. and a pressure of 30 MPa for a holding time of 90 min to obtain a bonded laminate composed of target and backing plate materials shown in FIG. 1.

The linear expansion coefficients of the target were 0.8% at 1000° C., 0.3% at 500° C., and 0.2% at 100° C., whereas the linear expansion coefficients of the backing plate were 1.0% at 1000° C., 0.5% at 500° C., and 0.2% at 100° C. Therefore, the maximum difference in linear expansion coefficient was 0.2 in a range of room temperature to 1000° C. Thus, the linear expansion coefficients of the target and the backing plate were notably proximate each other, and thereby there was absolutely no concern about warping, detachment, and cracking with the target.

The bonded laminate composed of the target and the backing plate was machined so that the diameter was 165.08 mm, the thickness of the backing plate portion was 2.05 mm, and the thickness of the target portion was 4.38 mm to obtain a sputtering target-backing plate assembly (the composition of the backing plate was Co-25Cr-3TiO₂ (mol %)). The assembly had an average pass through flux (PTF) of 50.0%. Since the assembly had such a high pass through flux (PTF), sputtering was possible. Table 1 shows this result.

### Example 6

As in Example 5, for a raw material powder for a magnetic material target, prepared were a Co powder having an average particle diameter of 1 μm, a Cr powder having an average particle diameter of 2 μm, a Pt powder having an average particle diameter of 2 μm, a TiO₂ powder having an average particle diameter of 1 μm, and a SiO₂ powder having an average particle diameter of 1 μm, and these were mixed at a composition of Co-16Cr-10Pt-3TiO₂-3SiO₂ (mol %) with a mixer.

Separately, for a backing plate, similarly prepared were a Co powder, a Cr powder, and a TiO₂ powder. These powders were mixed at a composition of Co-25Cr-3TiO₂ (mol %), hot-pressed and subjected to machining to prepare a backing plate material.

The magnetic permeability of this backing plate measured with a B-H meter (analyzer) was 1.0. The magnetic permeability of the target was significantly higher than this value.

The backing plate was machined to have a tub-shape having an inner diameter of 153.75 mm as in Example 2. The prepared backing plate was disposed in a carbon graphite die, and the target powder was placed on this backing plate material. Then, hot-pressing was performed in vacuum at a temperature of 1100° C. and a pressure of 30 MPa for a holding time of 90 min to obtain a bonded laminate composed of target and backing plate materials.

This bonded laminate was further machined to obtain a target-backing plate assembly, which is shown in FIG. 2. The shape and the size of the assembly in FIG. 2 are as follows: diameter (1): 161.98 mm, diameter (2): 153.75 mm, diameter (3): 165.18 mm, thickness (1): 4.35 mm, thickness (2): 6.38 mm, and thickness (3): 1.76 mm. The thicknesses of the thickest portion and the thinnest portion of the backing plate were adjusted to be 4.42 mm and 2.03 mm, respectively. Since the backing plate thus was tub-shape, there was absolutely no concern about warping, detachment, and cracking with the target.

The average pass through flux (PTF) of this assembly was 50.5% and was further improved compared with that in Example 5. Since the pass through flux (PTF) was thus high, sputtering was easily performed. Table 1 also shows this result.

### Example 7

For a raw material powder for a magnetic material target, a Co powder having an average particle diameter of 1 μm, a Cr powder having an average particle diameter of 2 μm, a TiO₂ powder having an average particle diameter of 1 μm, a SiO₂ powder having an average particle diameter of 1 μm, and a Cr₂O₃ powder having an average particle diameter of 1 μm, and these powders were mixed at a composition of Co-16Cr-3TiO₂-2SiO₂-3Cr₂O₃ (mol %) with a mixer.

Separately, for a backing plate, similarly prepared were a Co powder, a Cr powder, and a Ta₂O₅ powder. These powders were mixed at a composition of Co-22Cr-2Ta₂O₅ (mol %), hot-pressed and subjected to machining to prepare a backing plate material.

The magnetic permeability of this backing plate measured with a B-H meter (analyzer) was 1.0. The magnetic permeability of the target was significantly higher than this value.

And, the backing plate material was disposed in a carbon graphite die, and the raw material powder for a target was placed on this backing plate material. Then, hot-pressing was performed in vacuum at a temperature of 1100° C. and a pressure of 30 MPa for a holding time of 90 min to obtain a bonded laminate composed of target and backing plate materials shown in FIG. 1.

The linear expansion coefficients of the target were 0.7% at 1000° C., 0.3% at 500° C., and 0.2% at 100° C., whereas the linear expansion coefficients of the backing plate were 1.2% at 1000° C., 0.7% at 500° C., and 0.3% at 100° C. Therefore, the maximum difference in linear expansion coefficient was 0.5 in a range of room temperature to 1000° C. Thus, the linear expansion coefficients of the target and the backing plate were notably proximate each other, and thereby there was absolutely no concern about warping, detachment, and cracking with the target.

The bonded laminate composed of the target and the backing plate was machined so that the diameter was 165.08 mm, the thickness of the backing plate portion was 2.05 mm, and the thickness of the target portion was 4.38 mm to obtain a sputtering target-backing plate assembly (the composition of the backing plate was Co-22Cr-2Ta₂O₅ (mol %)). The assembly had an average pass through flux (PTF) of 50.8%. Since the assembly had such a high pass through flux (PTF), sputtering was possible. Table 1 shows this result.

### Example 8

As in Example 7, a Co powder having an average particle diameter of 1 a Cr powder having an average particle diameter of 2 μm, a TiO₂ powder having an average particle diameter of 1 μm, a SiO₂ powder having an average particle diameter of 1 and a Cr₂O₃ powder having an average particle diameter of 1 μm, and these powders were mixed at a composition of Co-16Cr-3TiO₂-2SiO₂-3Cr₂O₃ (mol %) with a mixer to prepare a raw material powder for a magnetic material target.

Separately, for a backing plate, similarly prepared were a Co powder, a Cr powder, and a Ta₂O₅ powder: they were mixed at a composition of Co-22Cr-2Ta₂O₅ (mol %), hot-pressed and subjected to machining to prepare a backing plate material.

The magnetic permeability of this backing plate measured with a B-H meter (analyzer) was 1.0. The magnetic permeability of the target was significantly higher than this value.

The backing plate was machined to have a tub-shape having an inner diameter of 153.75 mm as in Example 2. The prepared backing plate was disposed in a carbon graphite die, and the target powder was placed on this backing plate material. Then, hot-pressing was performed in vacuum at a temperature of 1100° C. and a pressure of 30 MPa for a holding time of 90 min to obtain a bonded laminate composed of target and backing plate materials.

This bonded laminate was further machined to obtain a target-backing plate assembly, which is shown in FIG. 2. The shape and the size of the assembly in FIG. 2 are as follows: diameter (1): 161.98 mm, diameter (2): 153.75 mm, diameter (3): 165.18 mm, thickness (1): 4.35 mm, thickness (2): 6.38 mm, and thickness (3): 1.76 mm. The thicknesses of the thickest portion and the thinnest portion of the backing plate were adjusted to be 4.42 mm and 2.03 mm, respectively. Since the backing plate thus was tub-shape, there was absolutely no concern about warping, detachment, and cracking with the target.

The average pass through flux (PTF) of this assembly was 51.4% and was further improved compared with that in Example 7. Since the pass through flux (PTF) was thus high, sputtering was easily performed. Table 1 also shows this result.

### Example 9

For a raw material powder for a magnetic material target, prepared were a Fe powder having an average particle diameter of 3 μm, a Pt powder having an average particle diameter of 2 μm, and a SiO₂ powder having an average particle diameter of 1 μm and were mixed at a composition of Fe-41 Pt-9SiO₂ (mol %) with a mixer.

Separately, for a backing plate, a Co powder, a Cr powder, and a SiO₂ powder were similarly prepared. These powders were mixed at a composition of Co-25Cr-9SiO₂ (mol %), hot-pressed and subjected to machining to prepare a backing plate material.

The magnetic permeability of this backing plate measured with a B-H meter (analyzer) was 1.0. The magnetic permeability of the target was significantly higher than this value.

And, the backing plate material was disposed in a carbon graphite die, and the raw material powder for a target was placed on this backing plate material. Then, hot-pressing was performed in vacuum at a temperature of 1100° C. and a pressure of 30 MPa for a holding time of 90 min to obtain a bonded laminate composed of target and backing plate materials shown in FIG. 1.

The linear expansion coefficients of the target were 0.7% at 1000° C., 0.3% at 500° C., and 0.2% at 100° C., whereas the linear expansion coefficients of the backing plate were 1.0% at 1000° C., 0.5% at 500° C., and 0.2% at 100° C. Therefore, the maximum difference in linear expansion coefficient was 0.3 in a range of room temperature to 1000° C. Thus, the linear expansion coefficients of the target and the backing plate were notably proximate each other, and thereby there was absolutely no concern about warping, detachment, and cracking with the target.

The bonded laminate composed of the target and the backing plate was machined so that the diameter was 165.08 mm, the thickness of the backing plate portion was 2.05 mm, and the thickness of the target portion was 4.38 mm to obtain a sputtering target-backing plate assembly (the composition of the backing plate was Co-25Cr-9SiO₂ (mol %)). The assembly had an average pass through flux (PTF) of 92.5%. Thus, the pass through flux (PTF) did not decrease, and thereby sputtering was possible. Table 1 shows this result.

### Example 10

As in Example 9, for a raw material powder for a magnetic material target, prepared were a Fe powder having an average particle diameter of 3 μm, a Pt powder having an average particle diameter of 2 μm, and a SiO₂ powder having an average particle diameter of 1 μm, and these were mixed at a composition of Fe-41 Pt-9SiO₂ (mol %) with a mixer.

Separately, for a backing plate, a Co powder, a Cr powder, and a SiO₂ powder were similarly prepared. These powders were mixed at a composition of Co-25Cr-9SiO₂ (mol %), hot-pressed and subjected to machining to prepare a backing plate material.

The magnetic permeability of this backing plate measured with a B-H meter (analyzer) was 1.0. The magnetic permeability of the target was significantly higher than this value.

The backing plate was machined to have a tub-shape having an inner diameter of 153.75 mm as in Example 2. The prepared backing plate was disposed in a carbon graphite die, and the target powder was placed on this backing plate material. Then, hot-pressing was performed in vacuum at a temperature of 1100° C. and a pressure of 30 MPa for a holding time of 90 min to obtain a bonded laminate composed of target and backing plate materials.

This bonded laminate was further machined to obtain a target-backing plate assembly, which is shown in FIG. 2. The shape and the size of the assembly in FIG. 2 are as follows: diameter (1): 161.98 mm, diameter (2): 153.75 mm, diameter (3): 165.18 mm, thickness (1): 4.35 mm, thickness (2): 6.38 mm, and thickness (3): 1.76 mm. The thicknesses of the thickest portion and the thinnest portion of the backing plate were adjusted to be 4.42 mm and 2.03 mm, respectively. Since the backing plate thus was tub-shape, there was absolutely no concern about warping, detachment, and cracking with the target.

The average pass through flux (PTF) of this assembly was 94.0% and was further improved compared with that in Example 9. Thus, the pass through flux (PTF) did not decrease, and thereby sputtering was easily performed. Table 1 also shows this result.

### INDUSTRIAL APPLICABILITY

The present invention can provide a sputtering target-backing plate assembly having a high average pass through flux (e.g., 50% or more) by producing the assembly by disposing a target raw material powder on a backing plate and sintering them. The present invention therefore has an excellent effect of allowing more stable sputtering to provide a product with a high quality.

Further, simultaneous sintering and bonding enables a fewer manufacturing process and shorten manufacturing period, and an effect of preventing a problem of detachment caused by an increase in temperature in sputtering is obtained, unlike bonding using a brazing material such as In.

Furthermore, the present invention allows use of a backing plate having a thin portion to be deeply eroded and a thick portion to be shallowly eroded, thereby allows a reduction in thickness of an expensive target, and can provide a sputtering target-backing plate assembly at a reduced cost and with an improved pass through flux (PTF). In addition, an effect can be obtained of reducing the raw material cost compared with that of an integrated target by using a material not containing Pt for the portion not to be eroded.

As described above, the present invention is capable of providing a technology that can provide a magnetic material sputtering target-backing plate assembly inexpensively and stably by simultaneously performing sintering of a raw material powder for a sputtering target prepared so as to have a desired composition and bonding of the target to a backing plate, and the assembly is therefore significantly useful as a magnetic material target.

1. A sputtering target-backing plate assembly comprising a magnetic material sputtering target and a backing plate wherein the backing plate has a lower magnetic permeability than that of the target.

2. The sputtering target-backing plate assembly according to claim 1, wherein the magnetic material target is of a material where at least one inorganic material selected from carbon, oxides, nitrides, carbides, and carbonitrides is finely dispersed in a metal phase.

3. The sputtering target-backing plate assembly according to claim 1, wherein the magnetic material target comprises 18 mol % or less of Cr and/or 25 mol % or less of Pt, and the remainder of Co and inevitable impurities.

4. The sputtering target-backing plate assembly according to claim 1, wherein the magnetic material target comprises 18 mol % or less of Cr and/or 45 mol % or less of Pt, and the remainder of Fe and inevitable impurities.

5. The sputtering target-backing plate assembly according to claim 4, wherein the magnetic material target further comprises at least one element selected from Ru, Ti, Ta, Si, B, and C in a total amount of 12 mol % or less.

6. The sputtering target-backing plate assembly according to claim 4, wherein the magnetic material target further comprises an oxide, nitride, carbide, or carbonitride of at least one element selected from Si, Ti, Ta, Co, Cr, and B or carbon in a total amount of 5 to 15 mol %.

7. (canceled)

8. The sputtering target-backing plate assembly according to claim 1, wherein the backing plate is of a non-magnetic material having a magnetic permeability of 1.0 or less.

9. The sputtering target-backing plate assembly according to claim 1, wherein the backing plate is of a metal phase only or a non-magnetic substance where at least one inorganic material selected from carbon, oxides, nitrides, carbides, and carbonitrides is finely dispersed in the metal phase.

10. The sputtering target-backing plate assembly according to claim 9, wherein the metal phase of the backing plate comprises Co and at least one element selected from Cr, Ti, Ta, Si, B, and C.

11. The sputtering target-backing plate assembly according to claim 9, wherein the inorganic material dispersed in the metal phase of the backing plate is an oxide, nitride, carbide, or carbonitride of at least one element selected from Si, Ti, Ta, Co, Cr, and B or carbon.

12. The sputtering target-backing plate assembly according to claim 1, wherein the backing plate comprises 19 to 40 mol % of Cr, and an oxide, nitride, carbide, or carbonitride of at least one element selected from Si, Ti, Ta, Co, Cr, and B or carbon in a total amount of 5 to 15 mol %, and the remainder of Co and inevitable impurities.

13. The sputtering target-backing plate assembly according to claim 1, wherein a maximum difference between linear expansion coefficients of the backing plate and the magnetic material target is 0.5 or less in a range of room temperature to 1000° C.

14. The sputtering target-backing plate assembly according to claim 1, wherein the backing plate is produced using scrap or waste of the sputtering target as a raw material.

15. A method of producing a sputtering target-backing plate assembly, the method comprising filling a die with a raw material powder prepared so as to have a composition of a magnetic material sputtering target, together with a backing plate and is hot-pressed, thereby being bonded to the backing plate simultaneously with sintering of the magnetic material target powder.

16. The method of producing a sputtering target-backing plate assembly according to claim 15, wherein the backing plate has a lower magnetic permeability than that of the target.

17. The method of producing a sputtering target-backing plate assembly according to claim 15, wherein the magnetic material target is of a material where at least one inorganic material selected from carbon, oxides, nitrides, carbides, and carbonitrides is finely dispersed in a metal phase.

18. The method of producing a sputtering target-backing plate assembly according to claim 15, wherein the magnetic material target comprises 18 mol % or less of Cr and/or 25 mol % or less of Pt, and the remainder of Co and inevitable impurities.

19. The method of producing a sputtering target-backing plate assembly according to claim 15, wherein the magnetic material target comprises 18 mol % or less of Cr and/or 45 mol % or less of Pt, and the remainder of Fe and inevitable impurities.

20. The method of producing a sputtering target-backing plate assembly according to claim 19, wherein the magnetic material target further comprises at least one element selected from Ru, Ti, Ta, Si, B, and C in a total amount of 12 mol % or less.

21. The method of producing a sputtering target-backing plate assembly according to claim 19, wherein the magnetic material target further comprises an oxide, nitride, carbide, or carbonitride of at least one element selected from Si, Ti, Ta, Co, Cr, and B or carbon in a total amount of 5 to 15 mol %.

22. The method of producing a sputtering target-backing plate assembly according to claim 15, wherein the backing plate is of a non-magnetic material having a magnetic permeability of 1.0 or less.

23. The method of producing a sputtering target-backing plate assembly according to claim 15, wherein the backing plate is of a metal phase only or a non-magnetic substance where at least one inorganic material selected from carbon, oxides, nitrides, carbides, and carbonitrides is finely dispersed in the metal phase.

24. The method of producing a sputtering target-backing plate assembly according to claim 23, wherein the metal phase of the backing plate comprises Co and at least one element selected from Cr, Ti, Ta, Si, B, and C.

25. The method of producing a sputtering target-backing plate assembly according to claim 23, wherein the inorganic material dispersed in the metal phase of the backing plate is an oxide, nitride, carbide, or carbonitride of at least one element selected from Si, Ti, Ta, Co, Cr, and B or carbon.

26. The method of producing a sputtering target-backing plate assembly according to claim 15, wherein the backing plate comprises 19 to 40 mol % of Cr, and an oxide, nitride, carbide, or carbonitride of at least one element selected from Si, Ti, Ta, Co, Cr, and B or carbon in a total amount of 5 to 15 mol %, and the remainder of Co and inevitable impurities.

27. The method of producing a sputtering target-backing plate assembly according to claim 15, wherein a maximum difference between linear expansion coefficients of the backing plate and the magnetic material target is 0.5 or less in a range of room temperature to 1000° C.

28. The method of producing a sputtering target-backing plate assembly according to claim 15, wherein the backing plate is produced using scrap or waste of the sputtering target as a raw material.
